(19) United States
(12) Patent Application Publication
(10) Pub. No.: US 2013/0098427 A1
(43) Pub. Date: Apr. 25, 2013

(54) PARABOLOID REFLECTORS

(71) Applicants: Frank Bretl, Corvallis, OR (US); Stephan R. Clark, Albany, OR (US); Scott Lerner, Portland, OR (US)

(72) Inventors: Frank Bretl, Corvallis, OR (US); Stephan R. Clark, Albany, OR (US); Scott Lerner, Portland, OR (US)

(21) Appl. No.: 13/280,663

(22) Filed: Oct. 25, 2011

(51) Int. Cl. H01L 31/052; H01L 31/18

(52) U.S. Cl. 136/246; 29/890.033

(57) ABSTRACT

An example of this disclosure relates to paraboloid reflectors. Another example of this disclosure relates to a collector panel including collector cells and paraboloid reflectors.

### BACKGROUND

Energy or radiation collector devices like solar devices oftentimes use a parabola reflector shape to reflect sun light onto collector cells. An example of a collector cell is a photovoltaic cell that converts collected light into electrical energy. A frame may hold the collector cells in the focal line or focal point of the reflector. An electrical network is provided to transport the collected and/or converted energy.

Sometimes the collector cell and the frame holding the collector cell are arranged in front of the reflector for collecting the reflected radiation, in that way blocking a radiation path to the reflector. Consequently, the radiation that is blocked cannot be collected by the collector cell. Furthermore, particular energy collector device arrangements occupy a lot of space. Furthermore, the materials and manufacturing processes used for certain energy collector devices can be relatively expensive.

### BRIEF DESCRIPTION OF THE DRAWINGS

For the purpose of illustration, certain examples of the present invention will now be described with reference to the accompanying drawings, in which:

FIG. 1 shows a diagrammatic side view of an example of a collector panel;

FIG. 2 shows an exploded view of an example of a collector panel;

FIG. 3 shows a diagrammatic cross sectional side view of an example of a collector panel;

FIG. 4 shows a diagrammatic cross sectional side view of an example of a radiation reflection panel;

FIG. 5 shows a diagrammatic cross sectional side view of another example of a collector panel;

FIG. 6 shows an example of a paraboloid reflector array in perspective view;

FIG. 7 shows an example of a collector panel module in perspective view;

FIG. 8 shows an example of the collector panel module of FIG. 7 in exploded view;

FIG. 9 shows an example of a diagram of a paraboloid reflector curve with relative dimensions and light rays;

FIG. 10 shows a view onto an example of a paraboloid surface with an off-axis section;

FIG. 11 shows a diagram of an example of a surface of a photovoltaic cell;

FIG. 12 shows a flow chart of an example of a method of collecting energy;

FIG. 13 shows a flow chart of an example of a method of manufacturing an collector panel; and

FIG. 14 shows a flow chart of another example of a method of manufacturing a collector panel.

### DETAILED DESCRIPTION

In the following detailed description, reference is made to the accompanying drawings. The examples in the description and drawings should be considered illustrative and are not to be considered as limiting to the specific example or element described. Multiple examples may be derived from the following description and/or drawings through modification, combination or variation of certain elements. Furthermore, it may be understood that also examples or elements that are not literally disclosed may be derived from the description and drawings by a person skilled in the art.

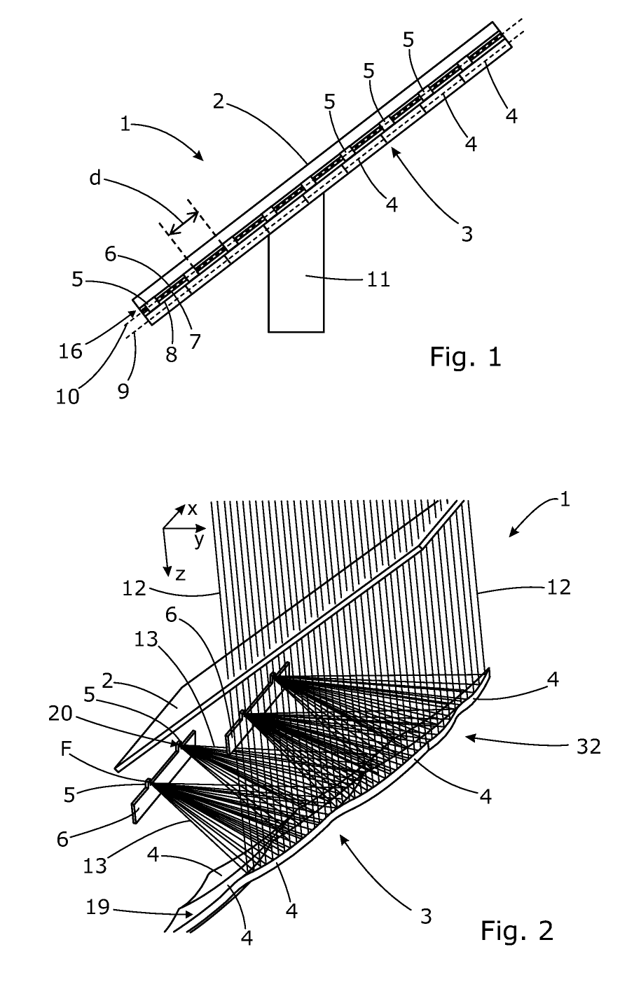

FIG. 1 shows a diagram of an example of a radiation collector panel 1. The collector panel 1 includes a collector cell array 16 having multiple collector cells 5 distanced from each other, as illustrated by distance D. The collector panel 1 includes at least one paraboloid reflector array 3 of equally shaped and equally oriented paraboloid reflectors 4. The paraboloid reflectors 4 reflect radiation onto the collector cells 5. The collector cells 5 collect the reflected radiation. The paraboloid reflectors 4 may serve to concentrate the radiation so as to increase the power per area on the collector cells 5 as compared to the input power per area on the reflector entrance aperture. In an example, the radiation is converted into another energy sort, for example into electrical energy. The collected energy is transported to an outside source.

In an example, the collector panel 1 is arranged to collect radiation. The radiation may include light. In an example, the collector cell array 16 converts the collected radiation to electrical energy.

In an example the collector panel 1 is a solar panel arranged to convert light into electricity. In an example, the collector cells 5 are photovoltaic cells, arranged to convert light into electrical energy. In an example, the paraboloid reflectors 4 are provided with a light reflecting surface, such as a mirror-like surface, and are arranged to reflect and concentrate light onto the corresponding photo voltaic cells 5. In other examples, the collected radiation may include other types waves or rays. The radiation may correspond to thermal energy, electro-magnetic or radio-signals, etc. In another example, the collector cells 5 are arranged to collect heat. In another example, the collector cells 5 are arranged to convert light into heat.

The paraboloid reflectors 4 are arranged to reflect and concentrate the radiation onto the collector cells 5. In an example, the collector panel 1 includes a planar radiation permeable panel 2 covering the collector cell array 16 and the paraboloid reflector array 3. The radiation permeable panel 2 may be a light permeable panel such as a glass plate, for protecting of the circuitry of the panel 1. For example, the collector cell array 16 and the paraboloid reflector array 3 are oriented so that a first virtual plane 9 intersects the collector cells 5 and a second virtual plane 10 intersects the paraboloid reflectors 4. The first and second virtual plane 9, 10 are parallel to the planar radiation permeable panel 2. These virtual planes 9, 10 are not physically present but are meant, in this disclosure, to define a planar shape and parallel arrangement of respective embodiments of the paraboloid reflector array 3, the collector cell array 16 and the radiation permeable panel 2, within the collector panel 1. In an example, the collector panel 1 includes a frame 8 for supporting the collector cells 5, for example for supporting the collector cells in said planar arrangement. In an example, the collector cell array 16 and the paraboloid reflector array 3 are arranged along the virtual planes 10, 9, respectively, parallel to the radiation permeable panel 2, so that a relatively planar collector panel 1 may be provided.

For example, the collector panel 1 includes an electrical network 6 connected to the collector cells 5, for example connected to photovoltaic cells. The collector panel 1 may include a thermal network 7 for transporting thermal energy, for example connected to the collector cells 5. For example, the thermal network 7 may be arranged to transport electrical energy from the collector cells 5 or to cool the collector cells 5. For example, the frame 8 may support the electrical and/or thermal network 6, 7, respectively. In an example, the collector panel 1 is connected to a support structure 11 for supporting the panel 1. For example, the support structure 11 includes a drive arranged to orient the paraboloid reflector array 3 towards the sun.

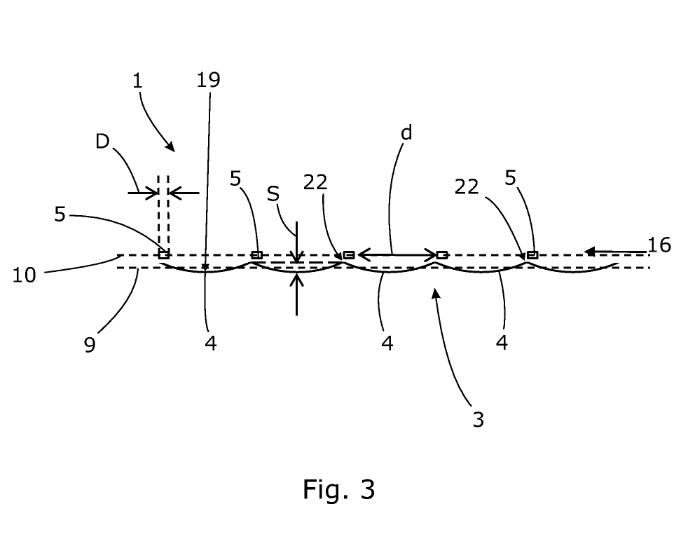

FIG. 2 illustrates examples of elements of a further example collector panel 1. The figure shows a panel 32 of a paraboloid reflector array 3 of multiple equally shaped and oriented paraboloid reflectors 4. Each paraboloid surface of the reflector 4 and the collector cell 5 may be arranged so that the reflected radiation is concentrated onto a receiving surface 20 of the collector cell 5. For example the focal point F of the reflector 4 may be located at least approximately onto the collector cell 5, for example in the form of a concentrated point, spot or region. In certain examples, paraboloid reflectors 4 and collector cells 5 may be adapted so that the focal points F of the reflectors are not located exactly on the reflected light receiving surface 20, for example to spread out the heat accumulation on the collector cell 5. This may be achieved by adjusting the distance d between the cells 5 and the reflectors 4 or by adjusting the curvature of the paraboloid shape of the reflector 4.

The arrangement of the energy collection panel 1 may allow for a relatively small collector cell 5. In an example, the collector cell 5 is a photovoltaic cell that has a largest cross sectional dimension of approximately 15 millimeters or less, or approximately 6 millimeters or less, that is a diameter D, a width or a height of approximately 15 millimeters or less, or approximately 6 millimeters or less. Having small collector cells 5 may block less incoming radiation thereby allowing more radiation to reach the reflectors 4.

For example, the electrical network 6 may connect the collector cells 5 to an outside source for transporting the converted energy. In the figure, the electrical network 6 is shown in the form of circuits that connect to the collector cells 5. The frame 8 may support the electrical network 6 and collector cells 5. In an example, the frame 8 is arranged to prevent blockage of incoming light rays 12 as much as possible. A thermal network 7 may be arranged in the same manner as the electrical network 6.

A planar collector panel 1 is diagrammatically illustrated in cross-section in FIG. 3. The collector panel 1 includes a planar, that is, relatively flat, paraboloid reflector array 3. All paraboloid reflectors 4 of the array 3 have the same orientation. The paraboloid reflectors 4 all intersect a first virtual plane 9 to obtain said planar arrangement. The paraboloid reflectors 4 have a sag S, here illustrated as the depth of the deepest point of the concave reflector surface 19 with respect to the edges of the reflectors 4. For example the sag S of the paraboloid reflectors 4 may be less than approximately 5 millimeters, or approximately 2.5 millimeter or less.

The collector cell array 16 may be arranged substantially parallel to the paraboloid reflector array 3. The collector cells 5 are intersected by the second virtual plane 10. In an example, the collector cell 5 is arranged near a respective edge 22 of the respective paraboloid reflector 4. By positioning the collector cells near the edges 22 no or little radiation will be blocked from reaching the reflector surface 19. In an example, the first and second virtual planes 9, 10 are parallel to each other, so that the collector cell array 16 and the paraboloid reflector array 3 form parallel planar arrangements, and a relatively flat collector panel 1 can be obtained.

The collector cells 5 have a distance d between each other. For example, the distance d between the collector cells 5 may be several times the diameter D, width or height of the collector cell 5. For example, the distance d between two cells 5 in the same array 16 may be approximately more than five or more than ten times the diameter D, width or height of the collector cell 5.

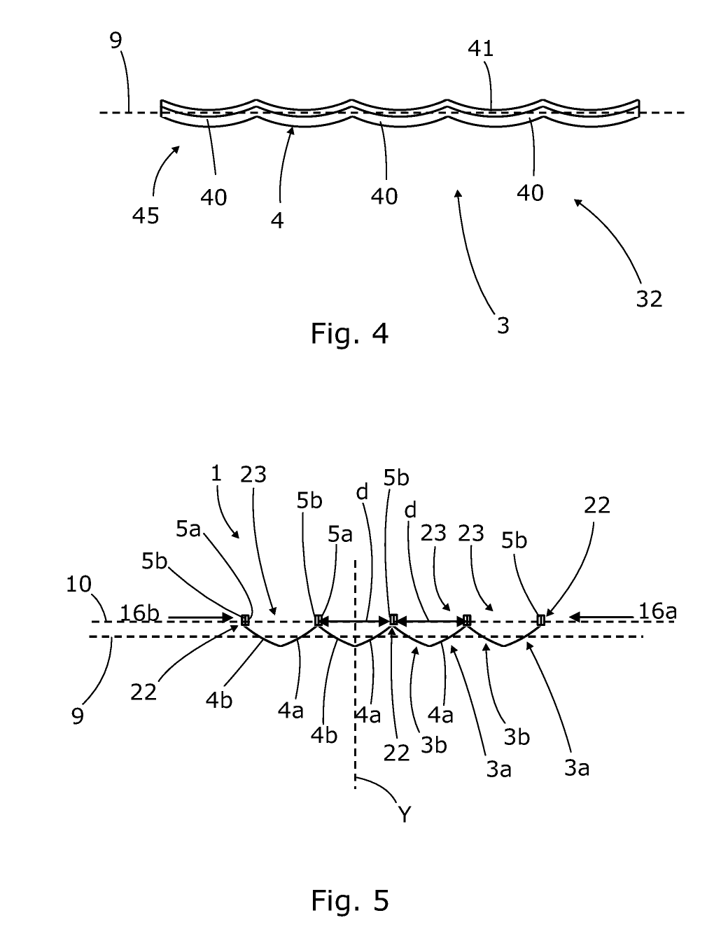

FIG. 4 shows an example of a paraboloid reflector array 3 including equally shaped and equally oriented paraboloid reflectors 4, intersected by a common virtual plane 9. The array 3 is shaped as a radiation reflection panel 32. The panel 32 includes an integrated massive panel 45 of paraboloid sections 40. The massive panel 45 may be integrally formed by the paraboloid sections 40. The massive panel 45 may be thermoformed, molded or otherwise plastically deformed. The massive panel 45 may substantially consist of a polymer material such as plastic or compound or another material that allows for plastic deformation. The panel 32 includes a reflective coating 41 over the integrated massive panel 45. The planar arrangement and low sag S may allow for the multiple paraboloid reflectors 4 to be readily coated with the reflective coating 41. The solid, integrated panel 32 may allow for cost efficient manufacture of the paraboloid reflector array 3. In other examples, each of the paraboloid sections 40 may be separately formed and later connected to form the panel 32.

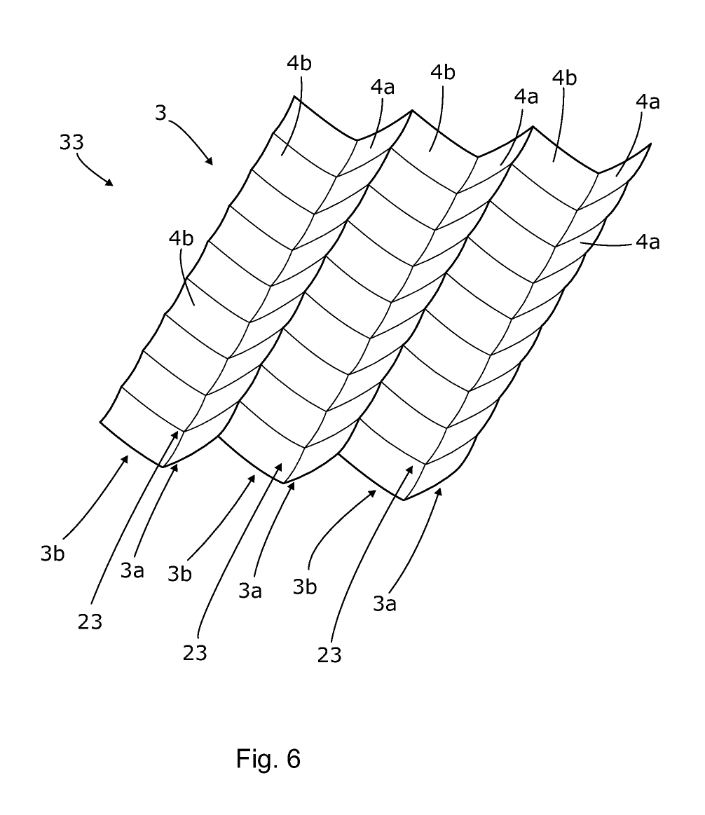

FIG. 5 shows an example of a collector panel 1 wherein the paraboloid reflector array 3a, 3b and the collector cell array 16a, 16b are in a different planar arrangement. Also here, a first virtual plane 9 intersects the paraboloid reflectors 4a, 4b and a second virtual plane 10 intersects the collector cells 5a, 5b.

The example of FIG. 5 has two paraboloid reflector sub-arrays 3a, 3b. A first paraboloid reflector sub-array 3a includes first paraboloid reflectors 4a in a first orientation, and a second paraboloid reflector sub-array 3b includes second paraboloid reflectors 4b in a second orientation. The first and second paraboloid reflectors 4a, 4b have inclined orientations with respect to each other, reflecting light onto opposite first and second collector cells 5a, 5b of first and second collector cell arrays 16a, 16b, respectively. The collector cells 5a, 5b of the respective collector cell sub-arrays 16a, 16b may be arranged in pairs. The first collector cells 5a of the first collector cell array 16a are distanced at a distance d. Also the second collector cells 5b of the second collector cell array 16b are distanced at a distance d.

The shown example reflector array 3 is arranged so that incoming light 12 is approximately parallel to an axis of symmetry Y of the paraboloid reflector array 3. Sunlight is reflected by the first paraboloid reflector 4a to the opposite collector cell 5a that is on top of the second paraboloid reflector 4b, and light is reflected by the second paraboloid reflector 4b to the opposite collector cell 5b that is on top of the first paraboloid reflector 4a.

In the shown example, opposite paraboloid reflectors 4a, 4b are turned towards each other, so that parallel gutter-like arrangements 23 are formed next to each other, extending into the sheet of the drawing. Each paraboloid reflector 4a, 4b reflects and concentrates the radiation as a point or spot onto the opposite collector cell 5a, 5b, respectively. The collector cells 5a, 5b may be arranged approximately in the focal points F of the paraboloid reflectors 4a, 4b, respectively.

The collector cells 5a, 5b are arranged near or on top of the respective top edges 22 of the collector cells 4b, 4a. In the example arrangement of FIG. 5, a minimal or low incoming radiation blockage by the collector cells 5 and electrical network 6 may be obtained because these are arranged above the respective edges 22 of the opposite reflectors 4a, 4b.

FIG. 6 shows a perspective view of an example of a panel 33 of a paraboloid reflector array 3, having a planar arrangement, similar to the example shown in FIG. 5. The paraboloid reflector array includes first and second paraboloid reflector sub-arrays 3a, 3b of first and second paraboloid reflectors 4a, 4b, respectively, forming parallel gutter-like arrangements 23.

FIG. 7 shows an example of a collector panel module 25 having two differently oriented paraboloid reflector sub-arrays 3a, 3b, similar to FIGS. 5 and 6. In itself, the collector panel module 25 may represent a collector panel 1. A frame 8 supports the paraboloid reflector sub-arrays 3a, 3b. In the shown example, each sub-array includes five paraboloid reflectors 4a, 4b. The first paraboloid reflector 4a has an orientation towards the corresponding collector cell 5a (only one collector cell 5b is shown in FIG. 7) arranged on top of the edge 22 of the opposite paraboloid reflector 4b. The frame 8 may provide for a support for the paraboloid reflector array 3, the collector cell array 16, as well as the electrical and thermal network 6, 7 for transporting the electrical and thermal energy, respectively, and for allowing easy mounting of the entire collector panel module 25. For example, a larger collector panel 1 may be construed through multiple collector panel modules 25.

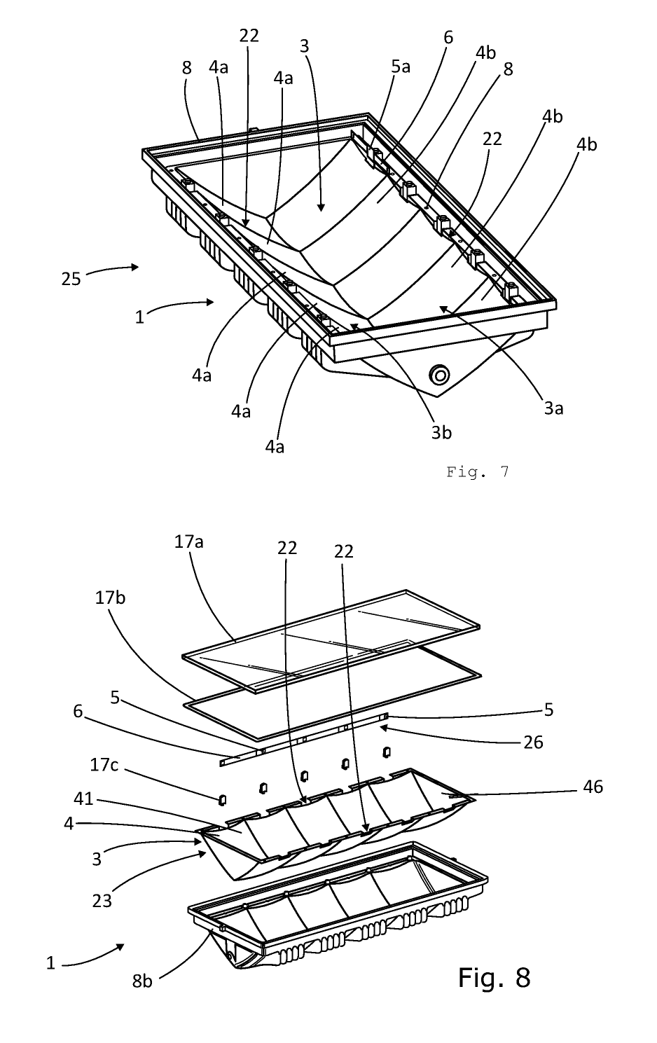

FIG. 8 shows an example of an exploded view of the collector panel module 25 of FIG. 7. From top to bottom, the figure shows a glass cover 17a and a seal feature 17b that are rectangle shaped. In mounted condition the glass cover 17a and the seal feature 17b may extend along the edges 22 of the paraboloid reflectors 4a, 4b, for example for keeping water and other contaminants out of the system while allowing light to pass through.

An energy collecting strip 26 may be provided. The strip 26 may include collector cells 5 and an electrical network 6 for transporting the electrical energy collected by the cells 5. The energy collecting strip 26 may be arranged to readily mount the collector cell array 16 on the frame 8. The frame 8 may include mounting pieces 17c, for example for mounting or fixing the collector cells 5 or the energy collecting strip 26. The collector panel module 25 may further include the integrally shaped paraboloid reflector array 3. In the shown example, the array 3 includes a molded or thermoformed tray 46 with paraboloid sections and a reflective coating 41. Furthermore a frame-tray 8b may be provided for supporting the paraboloid reflector array 3, the collector cell array 16 and/or a electrical or thermal network 6, 7 (e.g. see FIG. 1). The frame-tray 8b may be arranged to allow easy mounting onto a further support structure 11 of the collector panel module 25 (e.g. see FIG. 1).

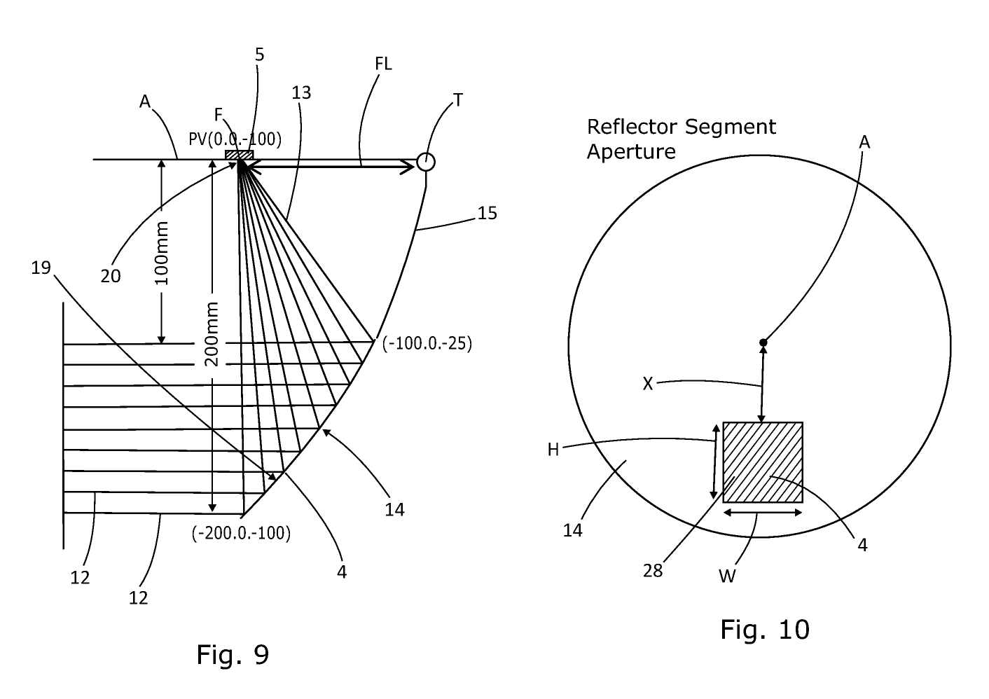

FIG. 9 illustrates a part of a paraboloid 15 having a central axis A, as may be used for defining the paraboloid reflector 4. As can be seen from FIG. 9, each paraboloid reflector 4 of the paraboloid reflector array 3 may be defined by an off axis section of a surface 14 of a paraboloid 15. The paraboloid reflector surface 19 is a section of the paraboloid 15. In an example, the collector cell 5 is arranged on the central axis A of the paraboloid 15 that defines the paraboloid reflector 4, in the focal point F of the paraboloid 15. During use of the reflector 4 the central axis A is arranged approximately parallel to the incoming radiation 12 so that all reflected radiation 13 falls onto the collector cell 5.

As can be seen from the example of FIGS. 9 and 10, the section of the paraboloid 15 that forms the reflector 4 is defined by a rectangle projection 28 onto the paraboloid surface 14. The height H and width W of the paraboloid section shown in FIG. 10 may represent the aperture of the reflector 4 with respect to the sun rays, as shown in FIG. 9. In the shown example, the aperture has a height H and a width W of 100 millimeters. The projection direction is parallel to a central axis A of the paraboloid 15. The paraboloid 15 has a focal length FL. The collector cell 5 is located in or near a point that is located at a focal length FL from the top T of the paraboloid 15, on or near the central axis A, in the focal point F. In the shown example, the rectangle projection 28 has a width W of 100 mm and a height H of 100 mm. The section starts at a distance X of 100 mm from the central axis, as measured in a direction perpendicular to the central axis A. For example, an edge of the section that is furthest away from the central axis A has a distance of 200 millimeters, from the central axis A, as measured perpendicular to the central axis A. For example the distance of the edge of the section that is furthest away from the central axis A may be the sum of the distance X between the closest edge of the section and the central axis A, and the height H of the section. In the shown example, the paraboloid 15 may have a base radius of approximately 200 millimeters, a conic constant of approximately −1 and a focal length FL of 100 millimeters. For example the rectangle projection that provides the section may have a width W or height H of approximately 5 to 400 millimeters.

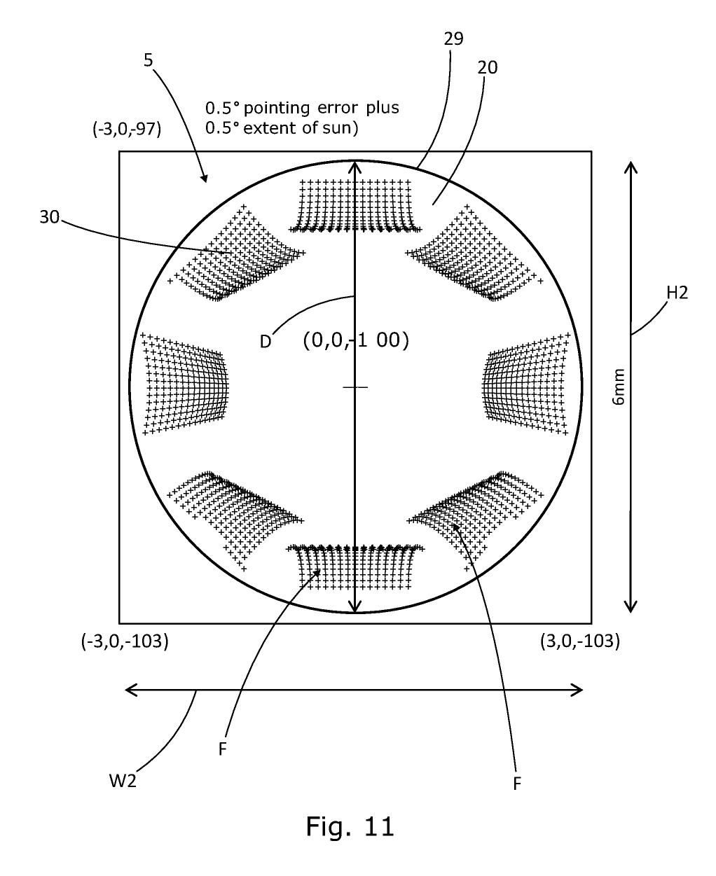

FIG. 11 shows an example of a view onto the surface 20 of the collector cell 5, illustrating examples of misalignment tolerances. The shown example collector cell 5 has a diameter D, for example of approximately 6 millimeters, or is rectangle or square shaped with a width W2 and height H2, for example of approximately 6 millimeters. In other examples, the width W2, height H2, or diameter D of the collector cell 5 may be approximately 15 millimeters or less. Near the edge 29 of the collector cell 5 bundles of rays 30 are illustrated, falling onto the surface 20. Each set of rays 30 corresponds to a simulated response of the reflector 4 to the incident light coming from the sun. In the simulation each angle of the sun that is modeled will have a bundle 30 of multiple rays 12 that enter the aperture of the reflector 4. Each ray 12 will be redirected by the reflector 4 and hit the collector cell surface 20 according to known light wave propagation laws. Each ray 13 will not hit collector surface 20 in the same location although originating from the sun under the same angle with respect to the central axis A. The fact that the rays hit the collector 5 on multiple locations may be due to imaging aberration of the mapping of the light rays 13 from the reflector 4 to the collector cell plane 20.

In FIG. 11 each bundle 30 shows how a particular set of light rays 13 of the same angle coming from the sun could be spread out on the collector surface 20. It illustrates an example of how big the collector cell 5 needs to be to collect the light from the sun when there is a misalignment between the collector cell 5 and the reflector 4 of approximately 0.5 degrees, and a angular subtense of the sun as seen by the reflector of approximately 0.25 degrees. In an example, the concentration of the light from the sun having a an angular subtense of +/−0.25 degrees with respect to the reflector entrance aperture will be reduced with respect to the aperture size of the reflector 4 to a value that is approximately 278 times smaller. This said, the example collector cell 5 may have an acceptance angle of approximately 0.75 degrees, corresponding to +/−0.25 degrees angular subtense for the sun and +/−0.5 degrees for optical misalignment.

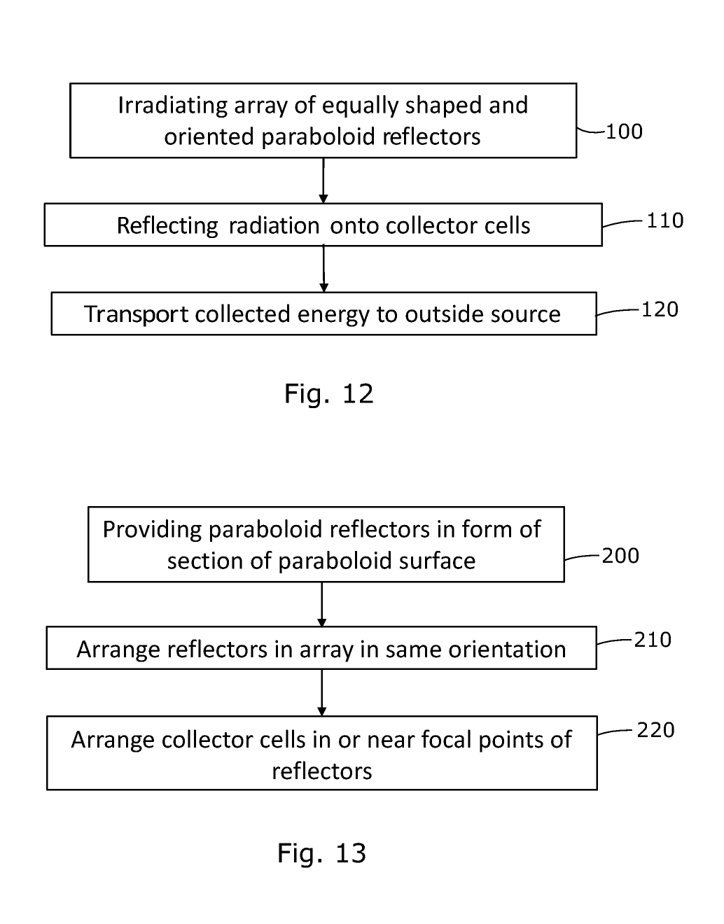

FIG. 12 shows a flow chart of an example of a method of collecting radiation. In an example, the method includes irradiating onto a panel 1 containing an array 4 of multiple equally shaped and equally oriented paraboloid reflectors 4, 4a, 4b (block 100). For example light is irradiated onto one or multiple paraboloid reflector arrays 3, 3a, 3b. In an example, the method includes that the reflectors 4, 4a, 4b reflect the radiation onto respective corresponding collector cells 5, 5a, 5b (block 110). For example, the collected energy is transported to an outside source (block 120).

FIG. 13 shows a flow chart of an example of a method of manufacturing a collector panel 1. In an example the method includes providing multiple paraboloid reflectors 4, 4a, 4b that are equally formed, each being formed as a section 28 of an at least approximately paraboloid surface 14 (block 200). In an example, the method includes arranging the paraboloid reflectors 4, 4a, 4b in an array 3, 3a, 3b so that they have the same orientation (block 210). In one example, the paraboloid reflectors 4, 4a, 4b include a solid, integrated panel 32, as explained with respect to FIG. 4. In another example, separate individual paraboloid reflectors 4, 4a, 4b are combined into one array 3 in a separate process step. In an example, the method includes arranging collector cells 5 approximately in the focal points F of the respective paraboloid reflectors 4, 4a, 4b (block 220).

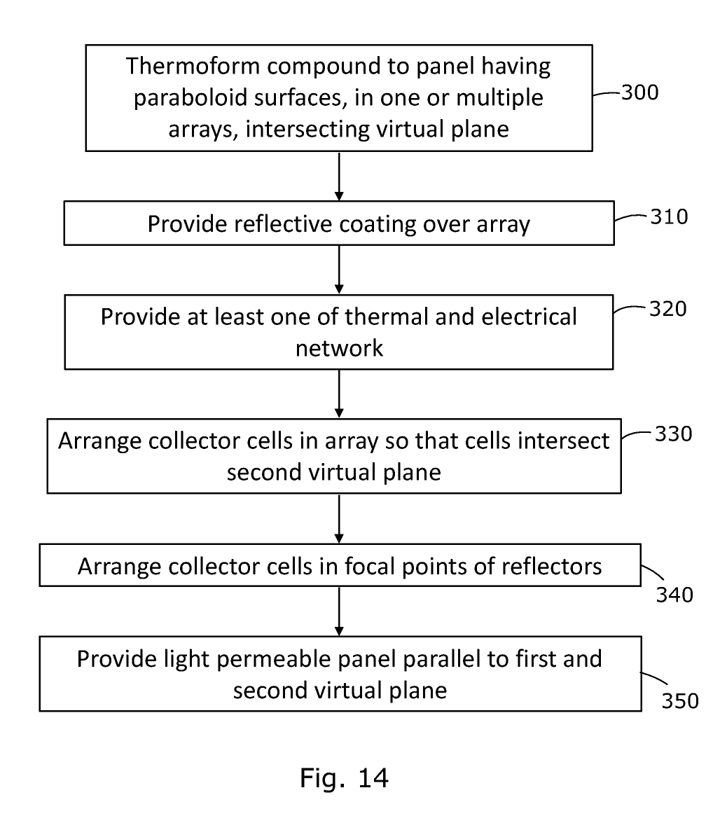

FIG. 14 shows a flow chart of another example of a method of manufacturing a collector panel 1. For example, the method includes

thermoforming a polymer such as a compound or plastic to form a solid, integrally molded panel 32, 33 with concave, at least approximately paraboloid, equally shaped sections 40 (block 300). All the paraboloid sections 40 may have the same orientation, or the paraboloid surfaces may be arranged in two sub-arrays 3a, 3b having two respective orientations. In the panel 32, 33, all the paraboloid shapes may be arranged so as to intersect a first virtual plane 9. In an example, the method includes providing a reflective coating over the sections 40 for forming the paraboloid reflector array 3, 3a, 3b (block 310). Coating may be readily applied for example because of the relatively planar arrangement of the panel 1, or for example in case the paraboloid surfaces have a relatively low sag S. In an example, the method may include providing at least one of an electrical or a thermal network 6, 7 to transport collected energy (block 320). For example a frame 8 may be provided for connecting the electrical and thermal network 6, 7 to the collector cells 5. The method includes arranging the collector cells 5 in an array so that all cells intersect a second virtual plane 10 (block 330), parallel to the first virtual plane. For example, the collector cells 5 are arranged in the focal points F of the reflectors 4 (block 340). In an example, the method includes providing a flat radiation permeable panel 2 covering the paraboloid reflector array 3, 3a, 3b, the at least one of the thermal and electrical network 6, 7, and the collector cell array 16, parallel to the first and second virtual plane 9, 10.

The above described features and steps may provide for a panel 1 for collecting, concentrating, converting and transporting radiation. The radiation may be collected through relatively small collector cells 5 that prevents blockage of radiation before it hits the reflectors 4, 4a, 4b, preventing affecting the aperture of the reflector 4. Also, a relatively simple manufacturing process may be provided. The panel 1 may be relatively planar and space efficient.

The above description is not intended to be exhaustive or to limit this disclosure to the examples disclosed. Other variations to the disclosed examples can be understood and effected by those skilled in the art from a study of the drawings, the disclosure, and the claims. The indefinite article “a” or “an” does not exclude a plurality, while a reference to a certain number of elements does not exclude the possibility of having more or less elements. A single unit may fulfil the functions of several items recited in the disclosure, and vice versa several items may fulfil the function of one unit. Multiple alternatives, equivalents, variations and combinations may be made without departing from the scope of this disclosure.

What is claimed:

1. Collector panel, comprising
at least one collector cell array having multiple collector cells distanced from each other, and
at least one paraboloid reflector array of equally shaped and equally oriented paraboloid reflectors arranged to reflect and concentrate radiation onto corresponding collector cells.

2. Collector panel according to claim 1, wherein the focal point of the respective paraboloid reflectors is located on the corresponding collector cells.

3. Collector panel according to claim 1, comprising a planar radiation permeable panel covering the collector cell array and the paraboloid reflector array, wherein the paraboloid reflector array and the collector cell array are oriented so that a first virtual plane intersects the paraboloid reflectors and a second virtual plane intersects the collector cells, the first and second virtual plane being parallel to the planar radiation permeable panel.

4. Collector panel according to claim 1, wherein
each paraboloid reflector is defined by an off axis section of a paraboloid surface, and
each section is defined by a rectangle projection onto the paraboloid surface, having a projection direction parallel to a central axis of the paraboloid, at a distance equal to the height of the rectangle from the central axis.

5. Collector panel according to claim 1, wherein the collector cells comprise photovoltaic cells.

6. Collector panel according to claim 1, wherein the collector cells have a largest dimension of less than approximately 15 millimeter.

7. Collector panel according to claim 1, wherein all paraboloid reflectors of the paraboloid reflector array have the same orientation.

8. Collector panel according to claim 1, comprising
first paraboloid reflector sub-arrays with first paraboloid reflectors in a first orientation, and
second paraboloid reflector sub-arrays with second paraboloid reflectors in a second orientation, and
corresponding first and second collector cell sub-arrays, wherein
the first and second paraboloid reflectors have inclined orientations with respect to each other, and
the first and second collector cell sub-arrays are arranged near respective edges of the first and second paraboloid reflector sub-arrays.

9. Collector panel according to claim 1, wherein each paraboloid reflector has a length and width smaller than 20 centimeters.

10. Collector panel according to claim 1, comprising a thermal and electrical network mounted on a single frame.

11. Collector panel according to claim 1, wherein the paraboloid reflectors comprise polymer containing and paraboloid shaped material and a reflective coating over the polymer containing material.

12. Method of collecting energy, comprising
irradiating a panel containing at least one array of multiple equally shaped and equally oriented paraboloid reflectors,
the reflectors reflecting and concentrating the radiation onto respective corresponding collector cells.

13. Method of manufacturing a collector panel, comprising
providing paraboloid reflectors that are equally formed, as a section of an at least approximately paraboloid surface,
arranging the paraboloid reflectors in an array so that they have the same orientation, and
arranging collector cells with distances between each other, approximately in focal points of the respective paraboloid reflectors.

14. Method according to claim 12, comprising
thermoforming compounds in the form of a panel having an array of concave, at least approximately paraboloid sections, and
providing a reflective coating over the sections for forming the paraboloid reflector array.

15. Method according to claim 12, arranging the paraboloid sections in two sub-arrays having two respective orientations.

16. Method according to claim 12, comprising
providing the paraboloid reflector array wherein the reflectors intersect a first virtual plane,
providing at least one of a thermal and electrical network,
providing the collector cell array wherein the collector cells intersect a second virtual plane, and
providing a flat radiation permeable panel covering the paraboloid reflector array, the at least one of the thermal and electrical network, and the collector cell array, parallel to the first and second virtual plane.

17. Radiation reflection panel for concentrating radiation onto collector cells, comprising at least one paraboloid reflector array of equally shaped and equally oriented paraboloid reflectors intersected by a common virtual plane.

18. Radiation reflection panel according to claim 16, comprising
a integrated solid panel of paraboloid sections, and
a reflective coating over the integrated massive panel.
